(19) United States
(12) Patent Application Publication
(10) Pub. No.: US 2026/0238892 A1
(43) Pub. Date: Aug. 13, 2026

(54) ELECTRONIC DEVICE

(71) Applicants: Innolux Corporation, Miaoli County (TW); InnoCare Optoelectronics Corporation, Tainan City (TW)

(72) Inventors: Cheng-Hsiao Lin, Miaoli County (TW); Hsin-Hung Lin, Tainan City (TW); Pei-Chih Liu, Miaoli County (TW); Sheng-Feng Huang, Miaoli County (TW)

(73) Assignees: Innolux Corporation, Miaoli County (TW); InnoCare Optoelectronics Corporation, Tainan City (TW)

(21) Appl. No.: 19/440,669

(22) Filed: Jan. 6, 2026

(30) Foreign Application Priority Data
Feb. 11, 2025 (TW) 114104954

(51) Int. Cl. H04N 25/46; H04N 25/443; H10F 39/00

(52) U.S. Cl. CPC H04N 25/46; H04N 25/443; H10F 39/8037; H10F 39/811

(57) ABSTRACT

An electronic device including a substrate, multiple pixel structures, a control element and a control line respectively disposed on the substrate is provided. The pixel structures include a first pixel structure and a second pixel structure arranged in a first direction. The control element is coupled to the first pixel structure and the second pixel structure, wherein the control element overlaps a portion of the first pixel structure and a portion of the second pixel structure in a normal direction of the substrate. The control line is coupled to the control element, wherein the control line extends toward a second direction. X% of a projection area of the control element in the normal direction of the substrate overlaps with the first pixel structure, and 1-X% of a projection area of the control element in the normal direction of the substrate overlaps with the second pixel structure, wherein X% is 40%-60%.

### CROSS-REFERENCE TO RELATED APPLICATION

This application claims the priority benefit of Taiwan application serial no. 114104954, filed on February 11, 2025. The entirety of the above-mentioned patent application is hereby incorporated by reference herein and made a part of this specification.

### BACKGROUND

### Technical Field

The disclosure relates to an electronic device, and in particular relates to an electronic device that performs a pixel binning operation by using a control element.

### Description of Related Art

In order to increase the signal reading speed of a pixel array in an electronic device, a pixel binning operation mode may be used to read the signal. In other words, by combining at least two pixels into one pixel to read signals, the photosensitivity and/or signal-to-noise ratio of the electronic device may be improved. However, the current operation mode may only read signals of multiple pixel structures sequentially, so that the existing electronic device has a relatively low signal reading speed. If signals of multiple pixel structures are read simultaneously, there is a possibility of signal distortion due to different sensing voltages in the pixel structures.

### SUMMARY

An electronic device, which may reduce the possibility of signal distortion when reading signals using a pixel binning operation mode, is provided in the disclosure.

Some embodiments of the disclosure provide an electronic device including a substrate, multiple pixel structures, a control element, and a control line. The pixel structures are disposed on the substrate, in which the pixel structures include a first pixel structure and a second pixel structure arranged in a first direction. The control element is disposed on the substrate and coupled to the first pixel structure and the second pixel structure, in which the control element overlaps a portion of the first pixel structure and a portion of the second pixel structure in a normal direction of the substrate. The control line is disposed on the substrate and coupled to the control element, in which the control line extends toward a second direction. X% of a projection area of the control element in the normal direction of the substrate overlaps with the first pixel structure, and 1-X% of a projection area of the control element in the normal direction of the substrate overlaps with the second pixel structure, in which X% is 40%-60%. A distance between a center of the control element and a first boundary of the first pixel structure in the first direction is Y% of a width of the first pixel structure in the first direction, and a distance between the center of the control element and a second boundary of the first pixel structure in the first direction is 1-Y% of the width of the first pixel structure in the first direction, in which Y% is 40%-60%.

Based on the above, in the electronic device provided in some embodiments of the disclosure, by disposing the control element and the control line, the sensing currents output by multiple pixel structures in the same group may be read simultaneously during the pixel binning read operation, thereby improving the signal reading speed of the electronic device and reducing the possibility of signal distortion. Furthermore, by turning off the control element, the operation of sequentially reading sensing currents output by multiple pixel structures in the same group may be performed, so that the electronic device provided by some embodiments of the disclosure has operational flexibility.

Furthermore, in the electronic device provided in some embodiments of the disclosure, the projection area of the control element may correspond to a portion of the first pixel structure and a portion of the second pixel structure. 40%-60% of the projection area of the control element overlaps with the first pixel structure, and the remaining projection area of the control element overlaps with the second pixel structure. In addition, the distance between the center of the control element and the boundary of the first pixel structure (or the second pixel structure) is 40%-60% of the width of the first pixel structure (or the second pixel structure). By establishing the aforementioned arrangement relationship between the control element and the first pixel structure and the second pixel structure, the difference between the signals read from the first pixel structure and the second pixel structure may be reduced.

### BRIEF DESCRIPTION OF THE DRAWINGS

FIG. 1A is a partial top view of an electronic device of an embodiment of the disclosure.

FIG. 1B is a circuit diagram of a control element in an electronic device according to an embodiment of the disclosure.

FIG. 1C is a circuit diagram of a control element in an electronic device of another embodiment of the disclosure.

FIG. 2 is a partial top view showing the arrangement relationship between a control element and pixel structures in an electronic device of an embodiment of the disclosure.

FIG. 3 is a partial top view showing the electrical connection relationship between a control element and pixel structures in an electronic device of an embodiment of the disclosure.

### DETAILED DESCRIPTION OF DISCLOSED EMBODIMENTS

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

Certain terms may be used throughout the disclosure and the appended patent claims to refer to specific elements. It should be understood by those skilled in the art that electronic device manufacturers may refer to the same elements by different names. The disclosure does not intend to distinguish between elements that have the same function but have different names. In the following description and patent claims, words such as "comprising", "including", and "having" are open-ended words, so they should be interpreted as meaning "including but not limited to...". Accordingly, when the terms "comprising", "including", and/or "having" are used in the description of this disclosure, they designate the presence of the corresponding feature, region, step, operation and/or component, but do not exclude the presence of one or more of a corresponding feature, region, step, operation, and/or component.

In the disclosure, wordings used to indicate directions, such as “up,” “down,” “front,” “back,” “left,” and “right,” merely refer to directions in the accompanying drawings. Therefore, the directional wordings are used to illustrate rather than limit the disclosure. In the accompanying drawings, the drawings illustrate the general features of the methods, structures, and/or materials used in the particular embodiments. However, the drawings shall not be interpreted as defining or limiting the scope or nature covered by the embodiments. For example, the relative sizes, thicknesses, and locations of the layers, regions, and/or structures may be reduced or enlarged for clarity.

When a corresponding component (e.g., a film layer or region) is referred to as being "on" another component, it may be directly on the other component or other components may be present therebetween. On the other hand, when a component is referred to as being "directly on" another member, there are no components in between. Additionally, when a component is referred to as being "on" another component, the two are in a top-down relationship when viewed from above, and the component may be above or below the other component, depending on the orientation of the device.

The terms "about", "equal to", "equal" or "same", "substantially" or "generally" are interpreted as within 20% of a given value or range, or interpreted as within 10%, 5%, 3%, 2%, 1%, or 0.5% of the given value or range.

The terms such as "first", "second", etc. used in the description and the patent claims are used to modify elements, which do not imply and represent that the (or these) elements have any previous ordinal numbers, and also does not represent the order of a certain element and another element, or the order of the manufacturing method. The use of these ordinal numbers is to only clearly distinguish an element with a certain name from another element with the same name. The same terms may not be used in the patent claims and the description, and accordingly, the first component in the description may be the second component in the patent claims.

It should be noted that, in the following embodiments, the features in several different embodiments may be replaced, reorganized, and mixed to complete other embodiments without departing from the spirit of the disclosure. As long as the features of the various embodiments do not violate the spirit of the disclosure or conflict with one another, they may be mixed and matched arbitrarily.

The electrical connection or coupling described in the disclosure may refer to direct connection or indirect connection. In the case of a direct connection, the end points of two elements on a circuit directly connect to each other, or connect to each other through a conductive wire. In the case of indirect connection, a switch, a diode, a capacitor, an inductor, other suitable elements, or a combination thereof, is between the end points of two elements on a circuit.

In the disclosure, the thickness, length, and width may be measured by adopting a measurement method such as an optical microscope (OM), and the thickness may be measured from a cross-sectional image in an electronic microscope, but not limited thereto. In addition, any two values or directions used for comparison may have certain errors. If a first value is equal to a second value, it implies that there may be an error of about 10% between the first value and the second value; if a first direction is perpendicular to a second direction, an angle between the first direction and the second direction may be between 80 degrees and 100 degrees; if the first direction is parallel to the second direction, an angle between the first direction and the second direction may be between 0 degrees and 10 degrees.

The electronic device of this disclosure may include, but is not limited to, detection device, display device, antenna device (e.g., liquid crystal antenna), light-emitting touch control device, splicing device, device having other suitable functions, or device having a combination of the aforementioned functions. The electronic device includes, but is not limited to, a rollable or flexible electronic device. The electronic device may comprise liquid crystal, light emitting diode (LED), quantum dot (QD), fluorescence, phosphor, other suitable materials or the combination thereof. The light emitting diode may for example include an organic light emitting diode (OLED), a micro/mini light emitting diode (micro-LED, mini-LED) or a quantum dot light emitting diode (QLED, QDLED), but not limited thereto. The electronic device may include electronic elements. Electronic elements may include passive and active elements, such as capacitors, resistors, inductors, diodes, transistors, and the like. The diode may include a light emitting diode or a photodiode. The light emitting diode may include an organic light-emitting diode (OLED), a mini light-emitting diode (mini LED), a micro light-emitting diode (micro LED), or a quantum dot light-emitting diode (quantum dot, QD, such as QLED, QDLED), or other suitable materials, or any arrangement and combination of the materials thereof, but not limited thereto. It should be noted that, the electronic device may be any arrangement and combination of the foregoing, but not limited thereto. In addition, the shape of the electronic device may be rectangular, circular, polygonal, a shape with curved edges, or other suitable shapes. The electronic device may have peripheral systems such as a driving system, a control system, a light source system, a shelf system, etc. to support a display device or a spliced device. It should be noted that, the electronic device may be any arrangement and combination of the foregoing, but not limited thereto. The electronic device may include multiple components, at least two of which may be assembled to form a composite object. Hereinafter, the detecting device is used as the electronic device to illustrate this disclosure, but this disclosure is not limited thereto.

Exemplary embodiments of this disclosure are exemplified below, the same reference numerals in the drawings and the descriptions indicate the same or similar parts.

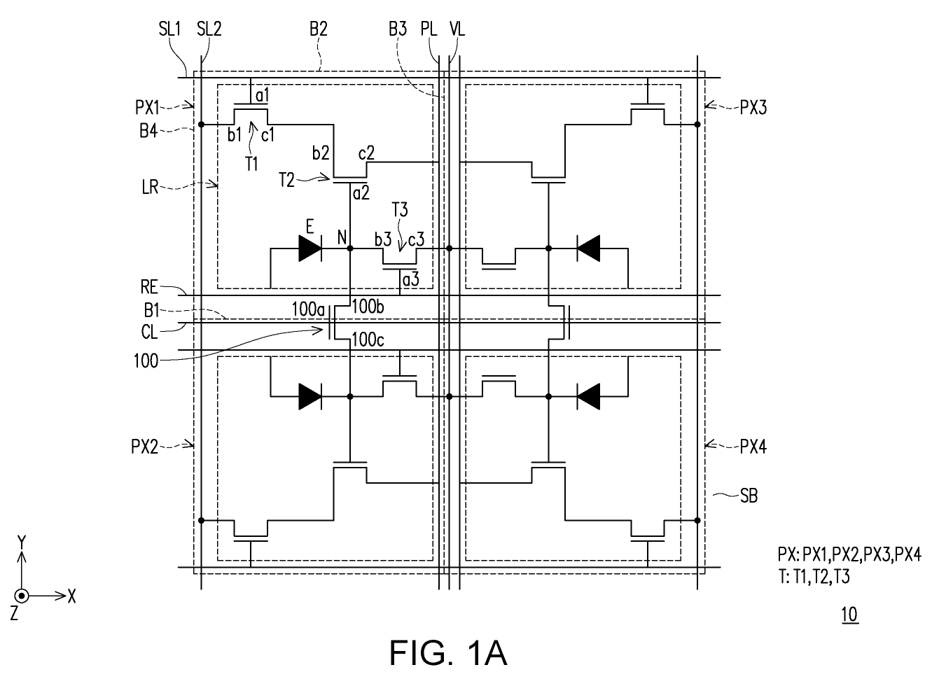

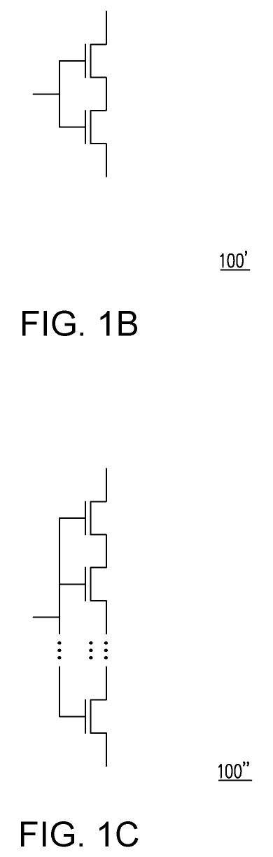

Referring to FIG. 1A, the electronic device 10 of this embodiment may be an electronic device with photosensitive functionality. For example, the electronic device 10 may be a flat panel detector (FPD), which may convert the received X-rays into electrical signals, and subsequently convert the electrical signals into images, but the disclosure is not limited thereto.

In this embodiment, the electronic device 10 includes a substrate SB, multiple pixel structures PX, a first signal line SL1, a second signal line SL2, a power line PL, a reset line RE, a reset voltage line VL, a control element 100, and a control line CL.

The material of the substrate SB may include a hard material, a soft material, or a combination thereof. For example, the material of the substrate SB may include quartz, sapphire, polymethyl methacrylate (PMMA), polycarbonate (PC), polyimide (PI), polyethylene terephthalate (PET), or other suitable materials, or a combination thereof, the disclosure is not limited thereto.

The pixel structures PX are disposed on the substrate SB. In this embodiment, the pixel structures PX include a first pixel structure PX1, a second pixel structure PX2, a third pixel structure PX3, and a fourth pixel structure PX4. From another perspective, in this embodiment, one of the pixel structures PX includes an electronic element E and a transistor T.

One of the pixel structures PX may have a boundary. In this embodiment, one of the pixel structures PX has four boundaries, in which end points of two adjacent boundaries are connected to form a rectangular structure in the normal direction Z of the substrate SB, but the disclosure is not limited thereto. Specifically, taking the first pixel structure PX1 as an example, the first pixel structure PX1 may have a boundary B1, a boundary B2, a boundary B3, and a boundary B4. The boundary B1 is a shared boundary between the first pixel structure PX1 and the second pixel structure PX2, and the boundary B2 is a shared boundary between the first pixel structure PX1 and another pixel structure (not shown) adjacent to the first pixel structure PX1 in the direction Y (orthogonal to the direction X), in which the boundary B1 corresponds to the boundary B2. The boundary B3 is a shared boundary between the first pixel structure PX1 and the third pixel structure PX3, and the boundary B4 is a shared boundary between the first pixel structure PX1 and another pixel structure (not shown) adjacent to the first pixel structure PX1 in the direction X, in which the boundary B3 corresponds to the boundary B4. In some embodiments, the normal direction Z of the substrate SB may be orthogonal to the direction X and the direction Y, but the disclosure is not limited thereto.

The electronic element E is disposed on the substrate SB and coupled to the transistor T. In this embodiment, the electronic element E is a photosensitive element, which may be configured to sense X-rays, but the disclosure is not limited thereto. Specifically, taking the first pixel structure PX1 as an example, the first pixel structure PX1 has a light sensing region LR. The light sensing region LR is defined by a region of the semiconductor layer (not shown) in the electronic element E where there is no light shielding layer (not shown) above (the normal direction Z of substrate SB) the semiconductor layer, but the disclosure is not limited thereto. In some embodiments, the electronic element E may include a lower electrode (not shown), an upper electrode (not shown), and a semiconductor layer (not shown), in which the semiconductor layer is disposed between the lower electrode and the upper electrode in the normal direction Z of the substrate SB. The material of the lower electrode and the upper electrode includes a transparent conductive material, which may be indium tin oxide (ITO), but the disclosure is not limited thereto. The material of the semiconductor layer includes amorphous silicon, but the disclosure is not limited thereto. In some other embodiments, the semiconductor layer may include single crystal material or polycrystalline material. In some embodiments, the semiconductor layer may include a first layer (not shown), an intrinsic layer (not shown), and a second layer (not shown). For example, the first layer, the intrinsic layer, and the second layer are stacked in this order in the normal direction Z of the substrate SB, but the disclosure is not limited thereto.

The transistor T is disposed on the substrate SB and coupled to the electronic element E. The transistor T may be a top gate thin film transistor or other thin film transistors well known to those skilled in the art, and the disclosure is not limited thereto. For example, the transistor T may include a gate (not shown), a source (not shown), a drain (not shown), and a semiconductor (not shown). The gate at least partially overlaps the semiconductor in the normal direction Z of the substrate SB, and the source and the drain are separated from each other and electrically connected to the semiconductor. In this embodiment, the transistor T includes a first transistor T1, a second transistor T2 and a third transistor T3. The first transistor T1 is a selection transistor, the second transistor T2 is a driving transistor, and the third transistor T3 is a reset transistor, but the disclosure is not limited thereto.

In this embodiment, the electronic element E, the transistor T and the other signal lines have the following coupling relationship, but the disclosure is not limited thereto.

The cathode end e1 (lower electrode) of the electronic element E may be coupled to the node N, and the anode end e2 (upper electrode) of the electronic element E may be coupled to a bias line (not shown) for providing a bias signal Vbias, but the disclosure is not limited thereto.

The control end a1 of the first transistor T1 is coupled to the first signal line SL1, the first end b1 of the first transistor T1 is coupled to the second signal line SL2, and the second end c1 of the first transistor T1 is coupled to the first end b2 of the second transistor T2.

The control end a2 of the second transistor T2 is coupled to the node N, the first end b2 of the second transistor T2 is coupled to the second end c1 of the first transistor T1, and the second end c2 of the second transistor T2 is coupled to the power line PL.

The control end a3 of the third transistor T3 is coupled to the reset line RE, the first end b3 of the third transistor T3 is coupled to the node N, and the second end c3 of the third transistor T3 is coupled to the reset voltage line VL.

In this embodiment, the first pixel structure PX1 and the second pixel structure PX2 may be disposed to mirror each other. Specifically, the electronic element E and the transistor T included in the first pixel structure PX1 and the second pixel structure PX2 respectively may be disposed to mirror each other on the two sides of the shared boundary B1, but the disclosure is not limited thereto.

Similarly, in this embodiment, the first pixel structure PX1 and the third pixel structure PX3 may also be disposed to mirror each other. Specifically, the electronic element E and the transistor T included in the first pixel structure PX1 and the third pixel structure PX3 respectively may be disposed to mirror each other on the two sides of the shared boundary B3, but the disclosure is not limited thereto.

The first signal line SL1 is disposed on the substrate SB and is coupled to the control end a1 of the first transistor T1. In this embodiment, the first signal line SL1 is a selection line, but the disclosure is not limited thereto. The first signal line SL1 may be configured to provide a selection signal to the first transistor T1 to turn it on. In some embodiments, the first signal line SL1 extends toward a direction X, but the disclosure is not limited thereto.

The second signal line SL2 is disposed on the substrate SB and is coupled to the first end b1 of the first transistor T1. In this embodiment, the second signal line SL2 is a read line, but the disclosure is not limited thereto. The second signal line SL2 may be configured to receive a signal (sensing current) generated by the electronic element E when the first transistor T1 is turned on, and the second signal line SL2 may transmit the sensing current to a processing circuit (not shown). The processing circuit may convert the sensing current into a sensing voltage and determine the intensity of the light received by the electronic device 10, but the disclosure is not limited thereto. In some embodiments, the second signal line SL2 extends toward a direction Y. In this embodiment, any second signal line SL2 is electrically connected to multiple pixel structures PX located in the same column. Specifically, one second signal line SL2 is electrically connected to the first pixel structure PX1 and the second pixel structure PX2 arranged in direction Y, and another second signal line SL2 is electrically connected to the third pixel structure PX3 and the fourth pixel structure PX4 arranged in direction Y.

The power line PL is disposed on the substrate SB and is coupled to the second end c2 of the second transistor T2. The power line PL may be configured to provide a high voltage (e.g., a power voltage) to the second transistor T2 so that the second transistor T2 may output current when it is turned on. In some embodiments, the power line PL extends toward a direction Y.

The reset line RE is disposed on the substrate SB and is coupled to the control end a3 of the third transistor T3. The reset line RE may be configured to provide a reset signal to the third transistor T3 to turn it on, to modulate the voltage of the control end a2 of the second transistor T2. In some embodiments, the reset line RE extends toward a direction X.

The reset voltage line VL is disposed on the substrate SB and is coupled to the second end c3 of the third transistor T3. The reset voltage line VL may be configured to provide a reset voltage signal so that the voltage of the node N is reset or modulated to a reset voltage, but the disclosure is not limited thereto. In some embodiments, the reset voltage line VL extends toward the direction Y. In this embodiment, the reset voltage line VL may overlap with the shared boundary B3 of the first pixel structure PX1 and the third pixel structure PX3 in the normal direction Z of the substrate SB.

The control element 100 is disposed on the substrate SB, and may include at least one transistor. In this embodiment, the control element 100 is coupled to the first pixel structure PX1 and the second pixel structure PX2 arranged in the direction Y. Specifically, the control end 100a of the control element 100 is coupled to the control line CL, the first end 100b of the control element 100 is coupled to the node N in the first pixel structure PX1, and the second end 100c of the control element 100 is coupled to the node N in the second pixel structure PX2. In addition, in this embodiment, another control element 100 is coupled to the third pixel structure PX3 and the fourth pixel structure PX4 arranged in the direction Y.

The control line CL is disposed on the substrate SB and is coupled to the control end 100a of the control element 100. The control line CL is configured to provide a control signal to the control element 100 to turn it on. In some embodiments, the control line CL extends toward a direction X. In this embodiment, the control line CL may overlap with the shared boundary B1 of the first pixel structure PX1 and the second pixel structure PX2 in the normal direction Z of the substrate SB.

In this embodiment, the electronic device 10 may be operated through the following steps.

First, a reset step is performed, in which a signal is provided to the control end a3 of the third transistor T3 by using the reset line RE to turn on the reset transistor T3, so that the voltage of the node N is reset or modulated to a reset voltage.

Next, an illumination step is performed, which turns off the third transistor T3 and causes the electronic element E to be irradiated with light for a specific time. The electronic element E may receive the light and generate a signal, so that the voltage of the node N is changed. The voltage of the node N may be affected by the intensity and/or time of the light irradiating the electronic element E.

Afterwards, a reading step is performed. After the electronic element E is irradiated with light for a specific period of time, a signal is provided to the control end a1 of the first transistor T1 by using the first signal line SL1 to turn on the first transistor T1. Therefore, the second transistor T2 to which a power supply voltage is applied by the power line PL at the second end c2 may output a current, and it may be provided to the second signal line SL2 via the turned-on first transistor T1. It is worth noting that the current output by the second transistor T2 is affected by the voltage of the node N, that is, it is affected by the intensity and/or time of the light irradiating the electronic element E. Subsequently, the sensing current may be converted into a sensing voltage and the intensity of the light received by the electronic device 10 may be determined through a processing circuit coupled to the second signal line SL2.

In this embodiment, by disposing the control element 100 and the control line CL, the sensing current output by the first pixel structure PX1 and the second pixel structure PX2 arranged in the direction Y may be read out simultaneously by turning on the control element 100 during the pixel binning read operation, thereby increasing the signal reading speed of the electronic device 10. In addition, since the control element 100 is coupled to the first pixel structure PX1 and the second pixel structure PX2 arranged in the direction Y, the respective node N in the first pixel structure PX1 and the second pixel structure PX2 may have the same voltage, which may reduce the possibility of signal distortion when using the second signal line SL2 to read the signals from the first pixel structure PX1 and the second pixel structure PX2. Furthermore, by turning off the control element 100, the operation of sequentially reading the sensing current output by the first pixel structure PX1 and the second pixel structure PX2 may be performed, so that the electronic device 10 has operational flexibility.

In addition, although FIG. 1A shows that the control element 100 has a single-gate structure, the disclosure is not limited thereto. In other embodiments, the control element 100 may be an equivalent transistor formed by connecting multiple single-gate transistors in series. For example, the electronic device 10 may include a control element 100' as shown in FIG. 1B, which is an equivalent transistor formed by connecting two single-gate transistors in series. Alternatively, the electronic device 10 may include a control element 100" as shown in FIG. 1C, which is an equivalent transistor formed by connecting more than two single-gate transistors in series. Based on this, in other embodiments, by including the control element 100' or the control element 100'' in the electronic device 10, the leakage current between two adjacent pixel structures arranged in the direction Y (e.g., the first pixel structure PX1 and the second pixel structure PX2) may be reduced when the control element 100' or the control element 100" is turned off.

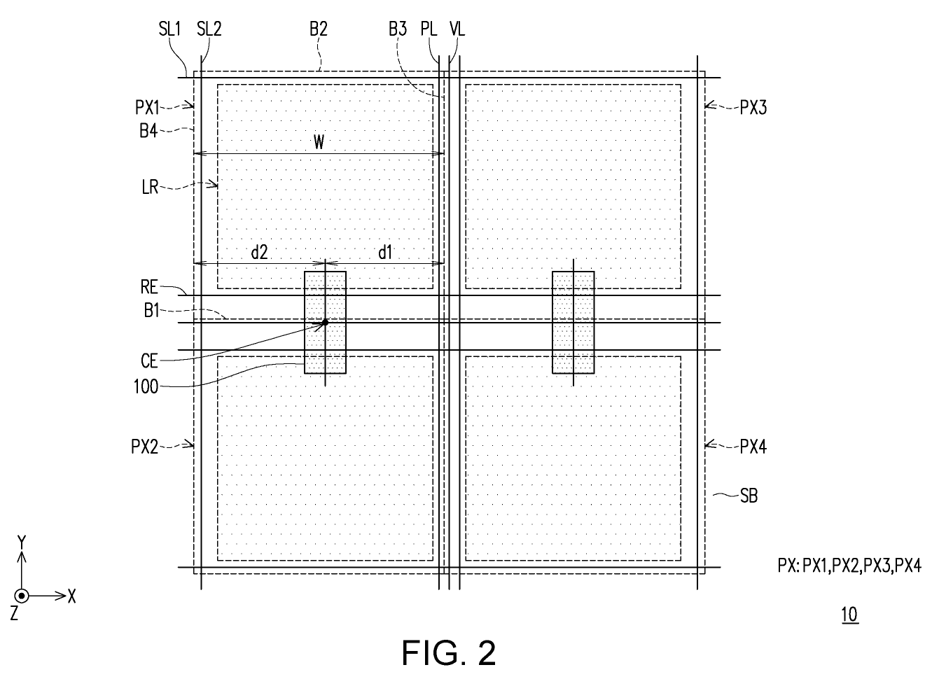

Referring to FIG. 2, the control element 100 overlaps a portion of the first pixel structure PX1 and a portion of the second pixel structure PX2 in the normal direction Z of the substrate SB. In other words, the control element 100 may overlap with a portion of the shared boundary B1 of the first pixel structure PX1 and the second pixel structure PX2 in the normal direction Z of the substrate SB. In detail, the projection area of the control element 100 in the normal direction Z of the substrate SB may correspond to a portion of the first pixel structure PX1 and a portion of the second pixel structure PX2. In this embodiment, X% of a projection area of the control element 100 in the normal direction Z of the substrate SB overlaps with the first pixel structure PX1, and 1-X% of the projection area of the control element 100 in the normal direction Z of the substrate SB overlaps with the second pixel structure PX2, in which X% is 40%-60%.

In addition, in this embodiment, the distance d1 between the center CE of the control element 100 and the boundary B3 of the first pixel structure PX1 (or the second pixel structure PX2) in the direction X is Y% of the width W of the first pixel structure PX1 (or the second pixel structure PX2) in the direction X, and the distance d2 between the center CE of the control element 100 and the boundary B4 of the first pixel structure PX1 (or the second pixel structure PX2) in the direction X is 1-Y% of the width W of the first pixel structure PX1 (or the second pixel structure PX2) in the direction X, in which Y% is 40%-60%.

By establishing the above arrangement relationship between the control element 100 and the first pixel structure PX1 and the second pixel structure PX2, the difference between the signals read from the first pixel structure PX1 and the second pixel structure PX2 may be reduced.

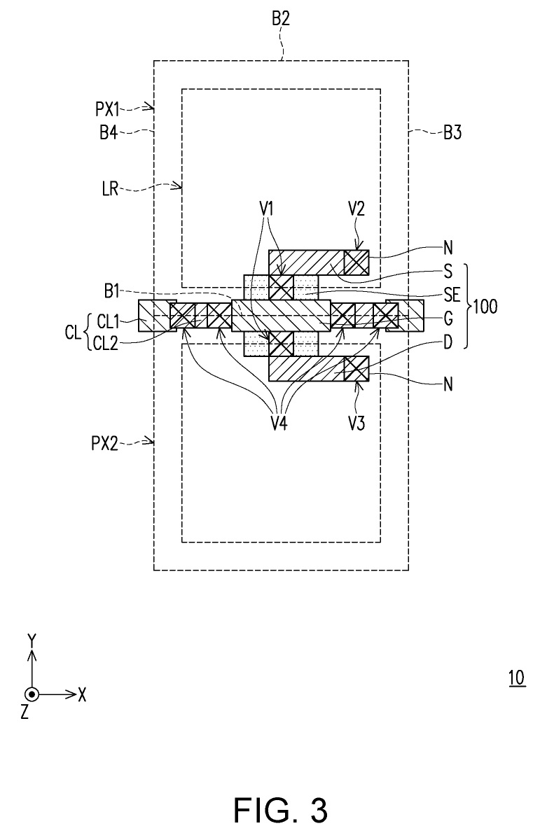

Referring to FIG. 3, the control element 100 of this embodiment is a top-gate thin film transistor, which includes a gate G, a source S, a drain D, and a semiconductor SE, but the disclosure is not limited thereto. The gate G at least partially overlaps the semiconductor SE in the normal direction Z of the substrate SB. The source S is separated from the drain D and is electrically connected to the semiconductor SE through the via V1. In this embodiment, the control element 100 may be electrically connected to the node N in the first pixel structure PX1 through the source S and the via V2, and the control element 100 may be electrically connected to the node N in the second pixel structure PX2 through the drain D and the via V3, but the disclosure is not limited thereto.

In this embodiment, the control line CL includes multiple layers of conductive structure, in which conductive structures in adjacent layers may be electrically connected to each other through vias. Specifically, referring to FIG. 3, the control line CL includes a control line segment CL1 and a control line segment CL2, the control line segment CL1 and the gate G of the control element 100 belong to the same layer, and the control line segment CL2 and the source S and the drain D of the control element 100 belong to the same layer, but the disclosure is not limited thereto. In this embodiment, the control line segment CL1 and the control line segment CL2 may be electrically connected to each other through the via V4.

By including multiple layers of conductive structure electrically connected to each other in the control line CL, the load of the control line CL may be reduced. In other words, the impedance value of the control line CL may be reduced.

To sum up, in the electronic device provided in some embodiments of the disclosure, by disposing the control element and the control line, the sensing currents output by multiple pixel structures in the same group may be read simultaneously during the pixel binning read operation, thereby improving the signal reading speed of the electronic device and reducing the possibility of signal distortion. Furthermore, by turning off the control element, the operation of sequentially reading sensing currents output by multiple pixel structures in the same group may be performed, so that the electronic device provided by some embodiments of the disclosure has operational flexibility.

In the electronic device provided in some other embodiments of the disclosure, the projection area of the control element may correspond to a portion of the first pixel structure and a portion of the second pixel structure. 40%-60% of the projection area of the control element overlaps with the first pixel structure, and the remaining projection area of the control element overlaps with the second pixel structure. In addition, the distance between the center of the control element and the two corresponding boundaries of the first pixel structure (or the second pixel structure) is 40%-60% of the width of the first pixel structure (or the second pixel structure). By establishing the aforementioned configurational relationship between the control element and the first pixel structure and the second pixel structure, the difference between the signals read from the first pixel structure and the second pixel structure may be reduced.

In the electronic device provided in some other embodiments of the disclosure, the control line includes multiple layers of conductive structure electrically connected to each other, which may reduce the load of the control line.

What is claimed is:

1. An electronic device, comprising:
a substrate;
a plurality of pixel structures, disposed on the substrate, wherein the pixel structures comprise a first pixel structure and a second pixel structure arranged in a first direction;
a control element, disposed on the substrate and coupled to the first pixel structure and the second pixel structure, wherein the control element overlaps a portion of the first pixel structure and a portion of the second pixel structure in a normal direction of the substrate; and
a control line, disposed on the substrate and coupled to the control element, wherein the control line extends toward a second direction,
wherein X% of a projection area of the control element in the normal direction of the substrate overlaps with the first pixel structure, and 1-X% of a projection area of the control element in the normal direction of the substrate overlaps with the second pixel structure,
wherein X% is 40%-60%.

2. The electronic device according to claim 1, wherein a distance between a center of the control element and a first boundary of the first pixel structure in the first direction is Y% of a width of the first pixel structure in the first direction, and a distance between the center of the control element and a second boundary of the first pixel structure in the first direction is 1-Y% of the width of the first pixel structure in the first direction, wherein Y% is 40%-60%.

3. The electronic device according to claim 1, wherein the control element is a single-gate transistor.

4. The electronic device according to claim 1, wherein the control element is an equivalent transistor formed by connecting a plurality of single-gate transistors in series.

5. The electronic device according to claim 4, wherein the control element is an equivalent transistor formed by connecting two of the single-gate transistors in series.

6. The electronic device according to claim 1, wherein the control line comprises multiple layers of conductive structure, wherein conductive structures of adjacent layers are electrically connected to each other through vias.

7. The electronic device according to claim 6, wherein the first pixel structure and the second pixel structure respectively comprise an electronic element and a transistor, and the electronic element is coupled to the transistor.

8. The electronic device according to claim 7, wherein the control line comprises a first control line segment and a second control line segment, wherein the first control line segment and a gate of the transistor belong to a same layer, and the second control line segment and a source and a drain of the transistor belong to a same layer.

9. The electronic device according to claim 1, further comprising:
a first signal line, disposed on the substrate and extending toward the second direction; and
a second signal line, disposed on the substrate and extending toward the first direction, wherein the second signal line is coupled to the first pixel structure and the second pixel structure to read signals from the first pixel structure and the second pixel structure.

10. The electronic device according to claim 9, wherein the first signal line is a selection line.

11. The electronic device according to claim 9, wherein the second signal line is a read line.

12. The electronic device according to claim 1, wherein the first pixel structure and the second pixel structure respectively comprise an electronic element and a transistor, and the electronic element is coupled to the transistor.

13. The electronic device according to claim 12, wherein the electronic element comprises a photosensitive element.

14. The electronic device according to claim 12, wherein the transistor comprises a selection transistor, a driving transistor, and a reset transistor.

15. The electronic device according to claim 1, wherein the first pixel structure and the second pixel structure have a third boundary that is shared, and the first pixel structure and the second pixel structure are disposed to mirror each other on two sides of the third boundary.

16. The electronic device according to claim 15, wherein the control line overlaps with the third boundary in the normal direction of the substrate.

17. The electronic device according to claim 1, wherein the pixel structures further comprise a third pixel structure, the first pixel structure and the third pixel structure have a first boundary that is shared, and the first pixel structure and the third pixel structure are disposed to mirror each other on two sides of the first boundary.

18. The electronic device according to claim 17, further comprising:
a reset voltage line, disposed on the substrate and extending toward the first direction, wherein the reset voltage line is coupled to the first pixel structure and the third pixel structure, and the reset voltage line overlaps the first boundary in the normal direction of the substrate.

19. The electronic device according to claim 1, wherein a pixel binning read operation is performed on the first pixel structure and the second pixel structure.

20. The electronic device according to claim 1, wherein the electronic device is a flat panel detector.
